(19) United States
(12) Patent Application Publication
(10) Pub. No.: US 2003/0136999 A1
(43) Pub. Date: Jul. 24, 2003

(54) Semiconductor device with deposited oxide

(76) Inventors: Robert L. Hodges, Carlsbad, CA (US); Frank R. Bryant, Denton, TX (US); Murray Robinson, Corinth, TX (US)

Correspondence Address: HEWLETT-PACKARD COMPANY, Intellectual Property Administration, P.O. Box 272400, Fort Collins, CO, 80627-2400, US

(21) Appl. No.: 10/052,313

(22) Filed: Jan. 18, 2002

(51) Int. Cl. H01L 29/76; H01L 21/00; H01L 21/84

(52) U.S. Cl. 257/314; 438/151; 438/585

(57) ABSTRACT

A semiconductor device includes a semiconductor substrate having a first surface, a pair of active areas formed in the first surface, a deposited oxide layer proximate the active areas, and a gate over the first surface between the pair of active areas.

### FIELD OF THE INVENTION

The present invention relates to semiconductor devices, and is more particularly related to a semiconductor device having a deposited oxide.

### BACKGROUND OF THE INVENTION

Semiconductor wafers are fabricated to produce hundreds of die therefrom. Each die often includes one or more drive transistors. Each drive transistor includes a gate electrode that is electrically isolated from the substrate by a thermally grown gate oxide (GOX). The GOX is between two isolated active regions that are doped in the opposite carrier type of the substrate. Normally no current can flow between the active regions, however, when an appropriate bias is applied to the gate, carriers are attracted to the silicon-GOX interface and with sufficient bias, the substrate beneath the gate can be inverted to form a conductive channel between the two active regions, thereby turning the device on. The bias needed to just begin to turn on the device, generally called the threshold voltage, is determined by the doping in the substrate, thickness of the oxide between the gate electrode and the substrate, charge in the oxide and composition of the gate electrode. Typically drive transistors are isolated from each other by a thermally grown Field Oxide (FOX) region in a semiconductor substrate using a process known in the art as a LOCOS (Local oxidation of silicon) process. Metal lines can be run over these regions of isolation oxide to interconnect the many single devices and thereby form circuits. If sufficient voltage is present on the conductor lines running over the isolation oxide regions, a parasitic transistor is created where the semiconductor substrate beneath the isolation oxide regions can be inverted, thereby forming a conductive channel allowing current to flow between two devices that should be electrically isolated, causing circuit failure. The threshold voltage of this parasitic transistor is determined by the same factors as the drive transistors; however, since the FOX is significantly thicker than the GOX, the threshold voltage of the parasitic devices is generally much higher than that of the drive transistors. Given this, it is clear that the FOX isolation regions should be designed with a high degree of care since both the thickness and quality of the FOX will determine the threshold voltage of the parasitic devices and therefore the maximum operating voltage that can be applied to a circuit.

The formation of the FOX region depletes dopants at the surface of the semiconductor substrate at the interface therewith. Since trapped charges in the FOX region and dopant concentration in the semiconductor substrate determine the threshold voltage of parasitic transistors, this dopant depletion and incorporation into the FOX region results in a lowering of the threshold voltage of the parasitic transistors and reduction in the maximum voltage that can be used during circuit operation without turning on the parasitic devices on the chip.

### SUMMARY OF THE INVENTION

In one embodiment, a semiconductor device includes a semiconductor substrate having a first surface, a pair of active areas formed in the first surface, a deposited oxide layer proximate the active areas, and a gate over the first surface between the pair of active areas.

These and other features of the present invention will become more fully apparent from the following description and appended claims, or may be learned by the practice of the invention as set forth hereinafter.

### DESCRIPTION OF THE DRAWINGS

To further clarify the above and other advantages and features of the present invention, a more particular description of the invention will be rendered by reference to specific embodiments thereof which are illustrated in the appended drawings. The same numbers are used throughout the drawings to reference like features and components. It is appreciated that these drawings depict only typical embodiments of the invention and are therefore not to be considered limiting of its scope. The invention will be described and explained with additional specificity and detail through the use of the accompanying drawings in which:

FIG. 1 is a cross-sectional view of one embodiment of the invention undergoing fabrication in which a semiconductor substrate has a layer of oxide deposited thereon, where a patterned a photoresist layer is upon the deposited layer of oxide.

FIG. 2 is a cross-sectional view of the embodiment of the invention seen in FIG. 1 after further processing in which an sloped etch of the deposited oxide has been performed to expose the semiconductor substrate where an active area is to be formed, and where the exposed portion of semiconductor substrate has been oxidized.

FIG. 3 is a cross-sectional view of the embodiment of the invention seen in FIG. 2 after further processing in which a layer of polysilicon has been deposited upon both the deposited oxide and the oxidized portion of the semiconductor substrate.

FIG. 4 is a cross-sectional view of the embodiment of the invention seen in FIG. 3 after further processing in which the layer of polysilicon has been patterned over the oxidized portion of the semiconductor substrate, and active regions have been formed within the semiconductor substrate.

FIG. 5 is a cross-sectional view of the embodiment of the invention seen in FIG. 4 after further processing in which a dielectric is deposited.

FIG. 6a is a cross-sectional view of the embodiment of the invention seen in FIG. 5 after further processing in which contacts through the dielectric have been metallized at the patterned layer of polysilicon and on the semiconductor substrate over active regions formed therein.

FIG. 6b is a cross-sectional view of another embodiment of the invention in which deposited oxide electrically isolates two field effect transistors.

FIG. 7 is a cross-sectional view of another embodiment of the invention undergoing fabrication in which a semiconductor substrate has an optional thermal oxide and a deposited oxide respectively thereon, where a patterned photoresist layer is upon the deposed oxide.

FIG. 8 is a cross-sectional view of the embodiment of the invention seen in FIG. 7 after further processing in which an etch is performed to expose the semiconductor substrate respectively through the optional thermal oxide and the deposited oxide, and where an oxide is grown upon the exposed surface of the semiconductor substrate.

FIG. 9 is a cross-sectional view of the embodiment of the invention seen in FIG. 8 after further processing in which a conductive layer has been formed upon the grown oxide and the deposited oxide.

FIG. 10 is a cross-sectional view of the embodiment of the invention seen in FIG. 9 after further processing in which the conductive layer and the grown oxide are patterned by an etch to form a gate electrode, an underlying gate oxide, and to expose the semiconductor substrate, and in which active regions are formed in the semiconductor substrate beneath its exposed surfaces.

FIG. 11 is a cross-sectional view of the embodiment of the invention seen in FIG. 10 after further processing in which a dielectric is deposited over the structure.

FIG. 12 is a cross-sectional view of the embodiment of the invention seen in FIG. 11 after further processing in which contacts through the dielectric have been metallized at the patterned conductive layer and on the semiconductor substrate over active regions formed therein.

FIG. 13 is a cross-sectional view of another embodiment of the invention in which in a thermal ink jet print head has been formed as a die on a semiconductor substrate, such as a portion of a silicon wafer, such that a gate electrode of a drive transistor is electrically isolated by a patterned, deposited oxide layer.

FIG. 14 is a perspective view of another embodiment of the invention in which a print cartridge has a print head that is also embodiment of the invention.

### DETAILED DESCRIPTION

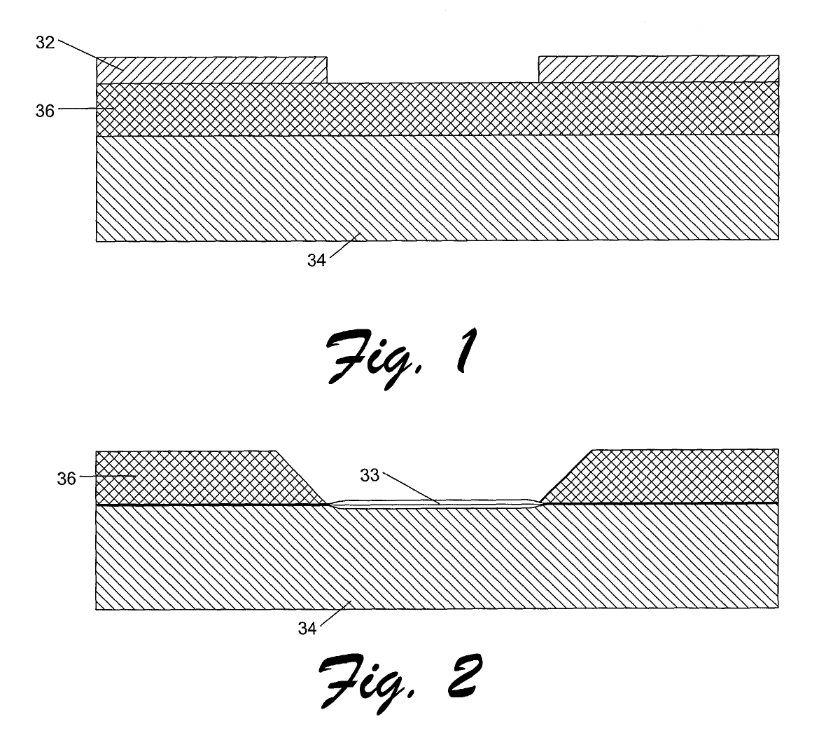

An illustration for presenting implementations of the method of the present invention is seen in FIGS. 1-6b for the fabrication of implementations of the structure of the present invention. FIG. 1 shows a semiconductor substrate 34, preferably composed of silicon, having a deposited oxide layer 36 thereon.

In the context of this document, the term “semiconductor substrate” is defined to mean any construction comprising semiconductive material, including but not limited to bulk semiconductive material such as a semiconductive wafer, either alone or in assemblies comprising other materials thereon, and semiconductive material layers, either alone or in assemblies comprising other materials. The term “substrate” refers to any supporting structure including but not limited to the semiconductor substrates described above. A substrate may be made of silicon, gallium arsenide, silicon on sapphire (SOS), epitaxial formations, germanium, germanium silicon, diamond, silicon on insulator (SOI) material, selective implantation of oxygen (SIMOX) substrates, and/or like substrate materials. Preferably, the substrate is made of silicon, which is ally single, crystalline.

Deposited oxide layer 36 can be a dielectric or insulator material that includes but is not limited to a wet or dry silicon dioxide (SiO₂), tetraethylorthosilicate (SiOC₂H₅)₄) (TEOS) based oxides, borophosphosilicate glass (BPSG), phosphosilicate glass (PSG), or borosilicate glass (BSG).

A pre-diffusion clean has preceded the formation of deposited oxide layer 36. Preferably, deposited oxide layer 36 will have a thickness in a range from about 10,000 to 15,000 Angstroms, and most preferably about 12,500 Angstroms.

An active area photoresist pattern follows in which a photoresist layer 32 is deposited upon deposited oxide layer 36. Photoresist layer 32 is then patterned to expose deposited oxide layer 36. A wet etch is performed upon the structure seen in FIG. 1. Preferably, the etch is an isotropic, buffered oxide etch of silicon dioxide that is performed for the purpose of exposing a surface on semiconductor substrate 34 beneath which an active area is to be formed within semiconductor substrate 34.

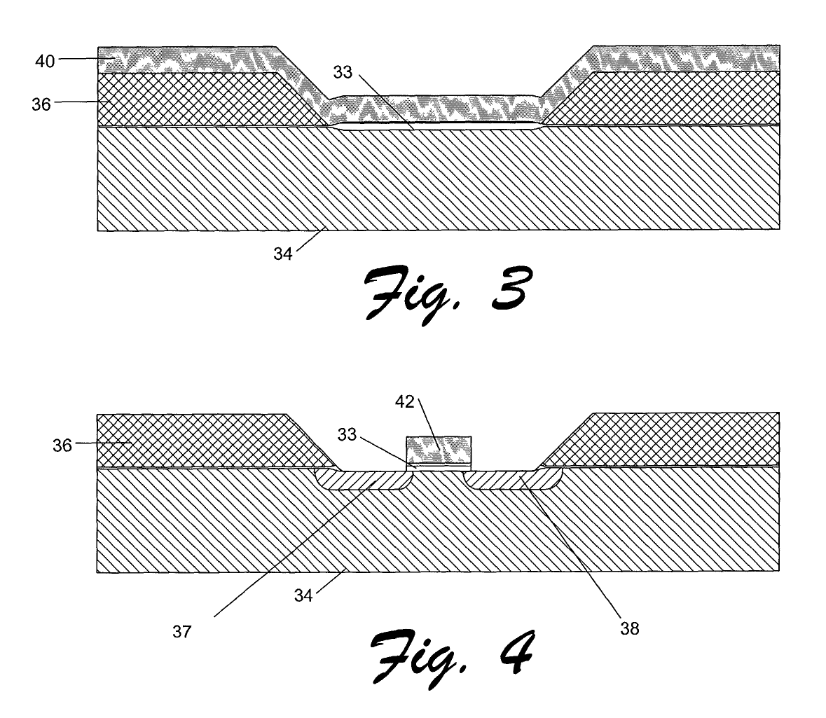

Also, the etch patterns the deposited oxide layer 36 as seen in FIG. 2. As seen in FIG. 2, photoresist layer 32 is stripped after the etch and a gate oxide 33 is thermally grown next to patterned, deposited oxide layer 36.

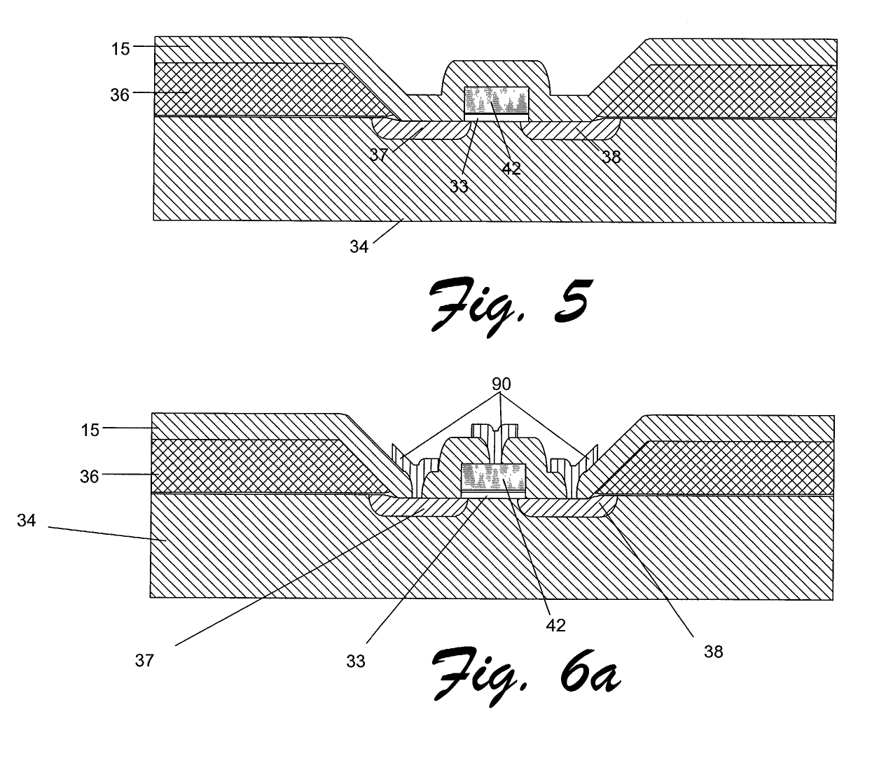

A pre-diffusion clean step is performed and a polysilicon layer 40 is formed upon patterned, deposited oxide layer 36 as seen in FIG. 3. In FIG. 4, polysilicon layer 40 is patterned to expose semiconductor substrate 34 through gate oxide 33 where active regions 37, 38 are formed. Active regions 37, 38 can be formed by implanting an N+ dopant into semiconductor substrate 34 which may have a p-type doping. The patterning of polysilicon layer 40 results in the formation of a gate oxide 33 associated with an electrode 82. The threshold voltage for gate electrode 42 increases away from active regions 37, 38 underneath each patterned, deposited oxide layers 36. As such, patterned, deposited oxide layers 36 have the same electrical effect as a pair of field oxide regions but without the detrimental problem of dopant depletion inherent to field oxide growth.

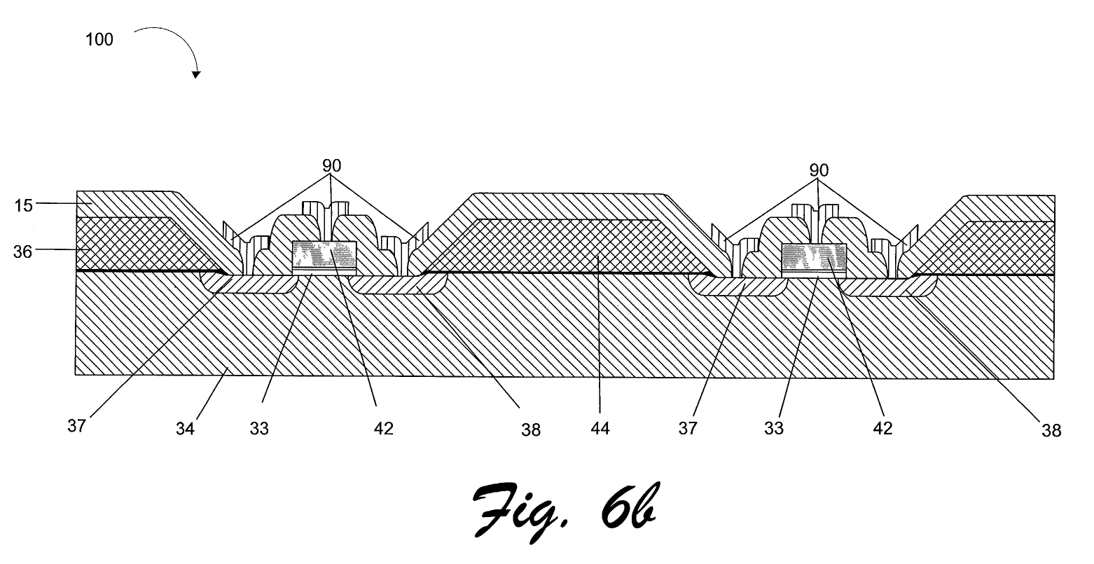

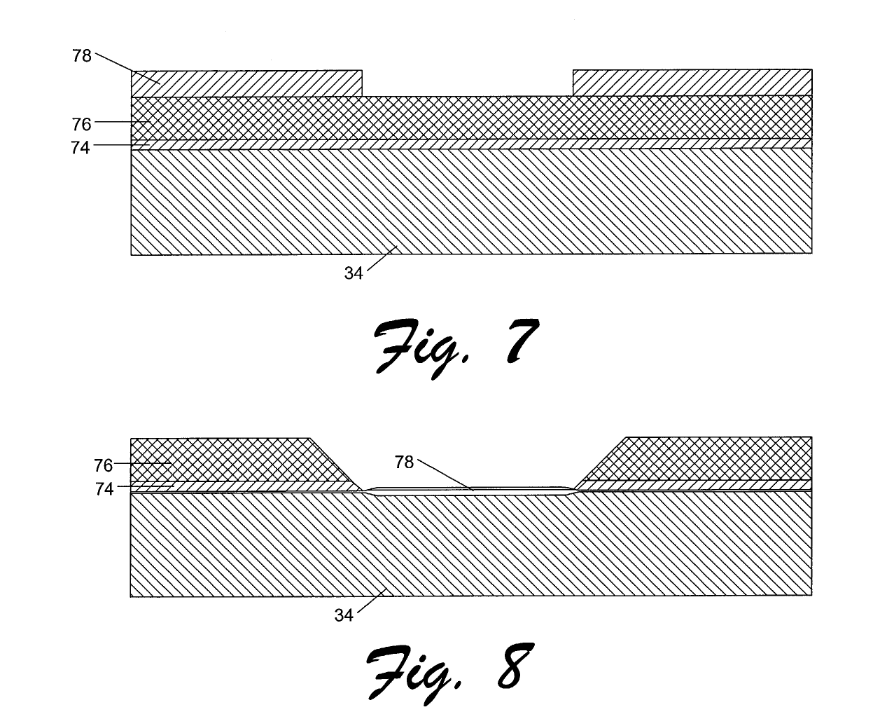

As seen in FIG. 5, a dielectric 15, which can be silicon dioxide, is deposited over the structure. Dielectric 15 is patterned to expose contacts on electrode 42 and on active regions 37, 38 as seen in FIG. 6a. After the contacts are opened, a metal is deposited and patterned to provide connections 90 to electrode 42 and active regions 37, 38 so as to complete the field effect transistor structure. Additional dielectric, contact and metal layers may be added as needed to provide sufficient wiring connections to fabricate circuits on the die.

FIG. 6b shows another implementation of the invention, where an electrical device 100 has a deposited oxide region 44 that electrically isolates first and second FETs. The first FET, seen at the left side of FIG. 6b, has gate electrode 42 with associated active regions 37, 38. The second FET, seen at the right side of FIG. 6b, has gate electrode 42 with associated active regions 37, 38. As such, the active region 37 of the second FET is adjacent to active region 38 of the first FET. Gate electrodes 42 are electrically isolated one from another by deposited oxide layer 44 there between which also prevents current from flowing between active region 38 of the first FET and active region 37 of the second FET.

An illustration for presenting another implementation of the method of the present invention is seen in FIGS. 7-12 for the fabrication of the structure of the present invention. FIG. 7 shows a semiconductor substrate 34 having an optional thermal oxide 74 thereon. A deposited oxide layer 76 is upon optional thermal oxide 74. A photoresist layer 78 is patterned and upon deposited oxide layer 76. When optional thermal oxide 74 is not present, deposited oxide layer 76 is upon semiconductor substrate 72.

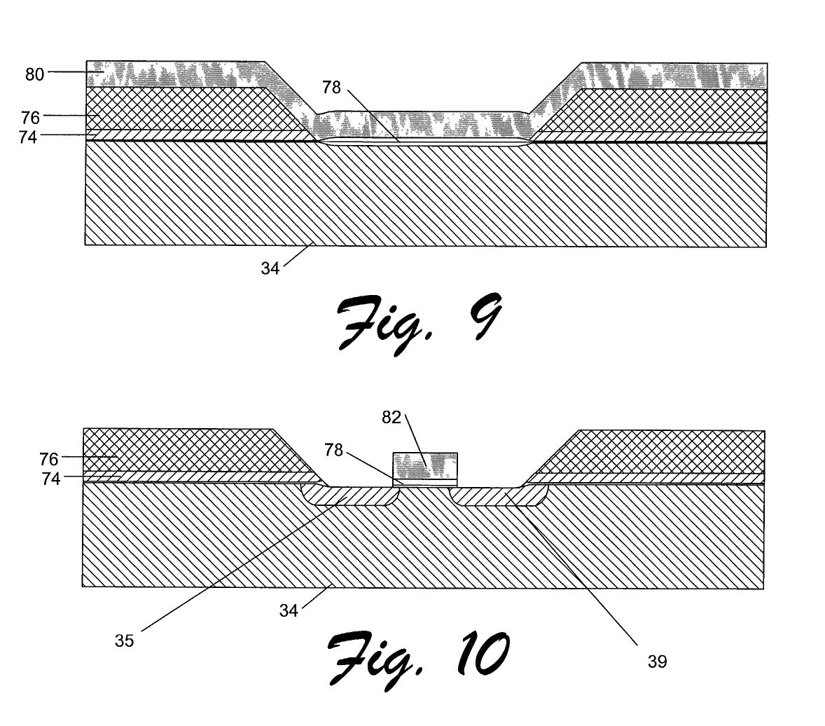

The results of a sloped, isotropic etch are seen in FIG. 8, where semiconductor substrate 34 is exposed by the etch of deposited oxide layer 76. The exposed surface on semiconductor substrate 34 is prepared for the formation of an active area there beneath.

In FIG. 8, a gate oxide 78 is formed by thermal oxidation of the exposed portion of semiconductor substrate 34. A layer of conductive material 80, such as polysilicon, is shown in FIG. 9 as being formed upon gate oxide 78 and deposited oxide layer 76. A photo resist mask is formed upon the layer of conductive material 80 and patterned. An etch is performed through the patterned photo resist mask so as to remove a portion of the layer of conductive material 80 and gate oxide 78 so as to expose semiconductor substrate 34. The photo resist mask is then stripped. The resultant structure, illustrated in FIG. 10, shows a gate electrode 82 upon gate oxide 78.

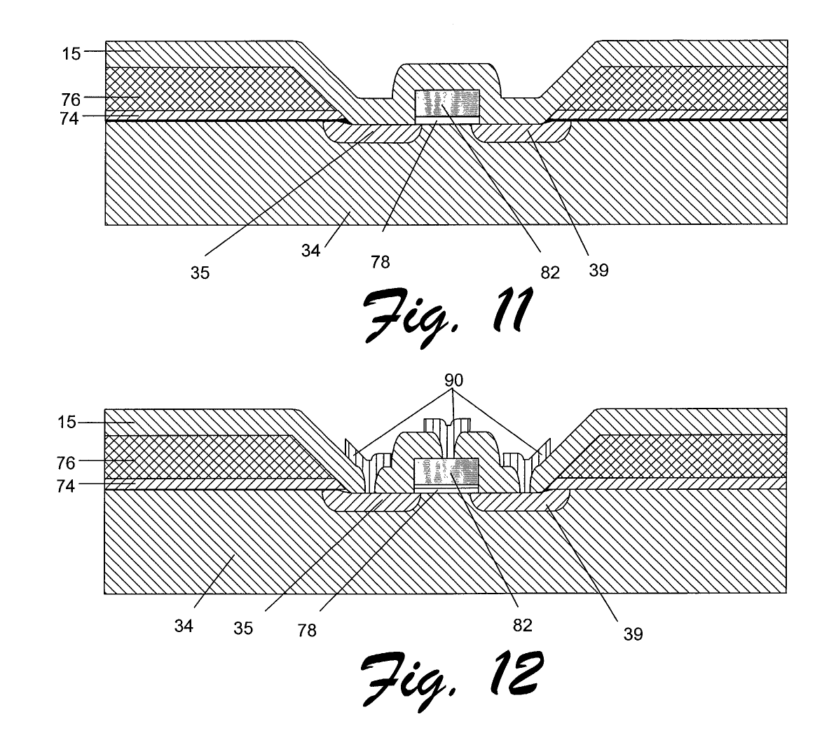

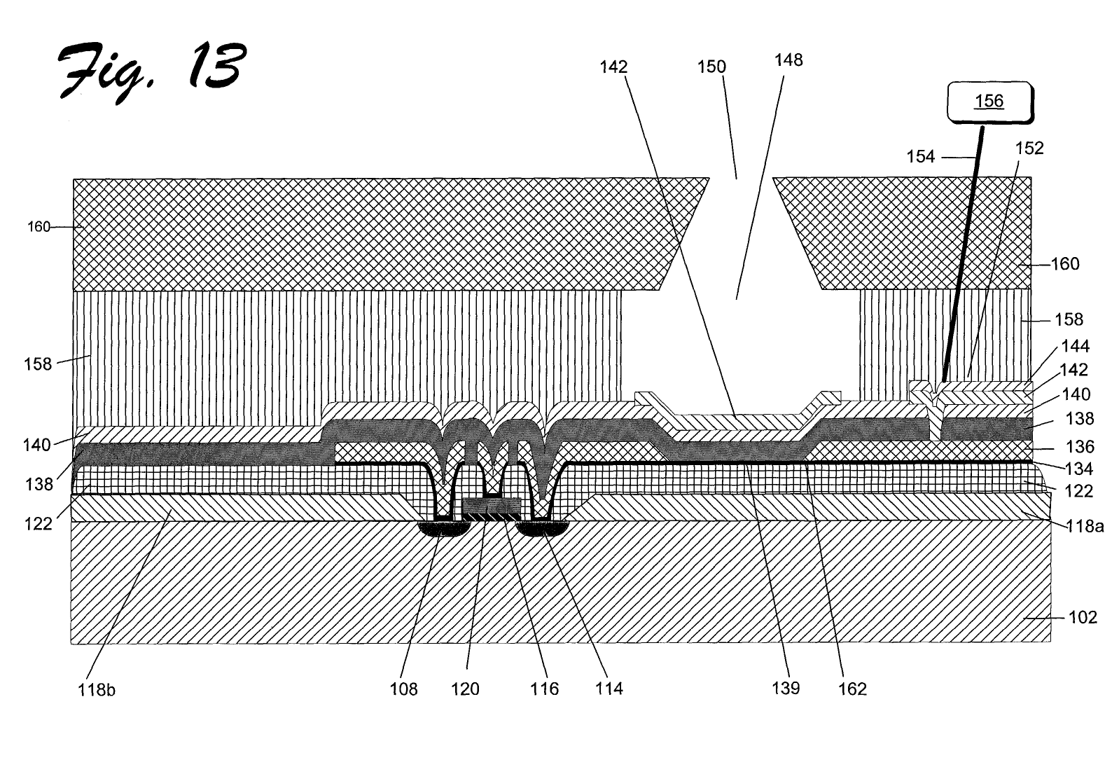

FIG. 11 shows the deposition of a dielectric 15, which can be silicon dioxide, over the structure. Dielectric 15 is patterned to expose contacts on electrode 42 and on active regions 35, 39 as seen in FIG. 12. After the contacts are opened, a metal is deposited and patterned to provide connections 90 to electrode 82 and active regions 35, 39 so as to complete the field effect transistor structure. The semiconductor device in FIG. 12 shows that electrode 82 is electrically isolated by the deposited oxide layers 76 and by optional thermal oxide portions 74. Additional dielectric, contact and metal layers may be added as needed to provide sufficient wiring connections to fabricate circuits on the die.

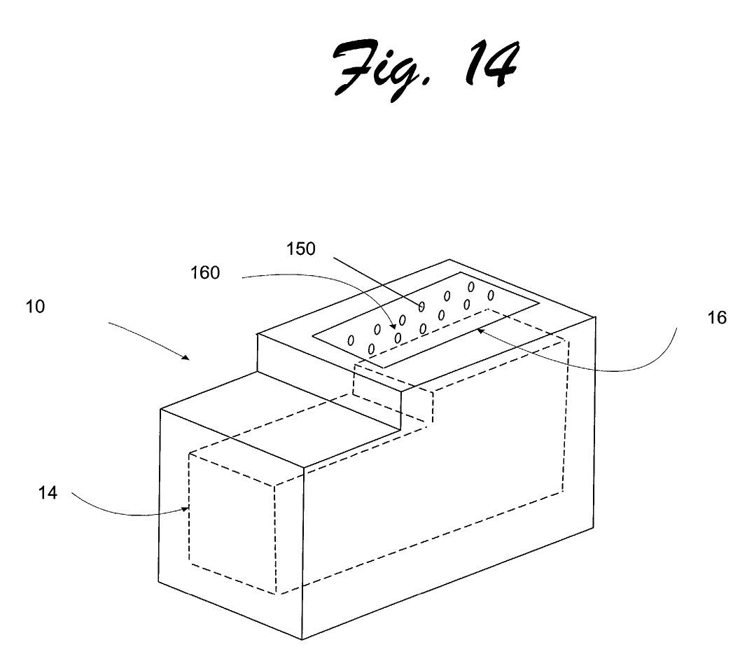

The semiconductor device of the present invention is applicable to the field of ink jet printing. In this field, a printing system has a controller, a media handling apparatus, and a print cartridge. A print head is included in a print cartridge. The print head has fluid ejection elements that can be heater resistors and/or piezoelectric actuators. By way of example, FIG. 13 shows an embodiment of the ink jet print head of the present invention, where a semiconductor substrate 102 forms the base layer of an ink jet print head. Preferably, semiconductor substrate 102 has a P doping. A drive transistor is illustrated in FIG. 13, where a first or primary active area 108 and a second or secondary active area 114 are formed within semiconductor substrate 102. A pair of patterned, deposited oxide layers 118a, 118b in the illustrated thermal ink jet print head have been formed by a process such as has been described with respect to FIGS. 2 and 8. A gate oxide layer 116 is adjacent to patterned, deposited oxide layers 118a, 118b and beneath a gate electrode 120. Deposited oxide layers 118a, 118b are adjacent to and make contact with each of the first and second active regions 108, 114. An electrical insulator layer 122 is formed upon the first and second active regions 108, 114 and also upon deposited oxide layers 118a, 118b. Electrical insulator layer 122 can be composed of doped silicon dioxide. A dielectric layer 138 is over electrical insulator layer 122 and can be formed by decomposition of a TEOS precursor gas.

A resistor layer 134 has a resistor portion 139 and makes contact with a metal layer 136. Metal layer 136, which is also referred to as “Metal 2” and can be composed of an aluminum-copper alloy, is upon resistor layer 134. A beveled point 162 of metal layer 136 contacts resistor portion 139. Dielectric layer 138 is upon metal layer 136 and a second passivation layer 140 is upon first passivation layer 138. First and second passivation layers 138, 140 can be composed of silicon nitride (e.g. Si₃N₄) and silicon carbide (e.g. SiC), respectively.

A first barrier or cavitation barrier layer 142, which can be composed of a tantalum-aluminum alloy, is upon second passivation layer 140. A noble metal, such as gold, is used to form an electrical contact 144 and is upon cavitation barrier layer 142. A barrier layer 158 has a nozzle plate 160 formed thereon. Barrier layer 158 is can be composed of an organic material, such as polyamide. Nozzle plate 160 can be formed from polyamide or a nickel composition. In an alternative implementation, barrier layer 158 and nozzle plate 160 can be one integral piece and can comprise a fast cross-linking polymer such as photoimagable epoxy (such as SU8 developed by IBM), photoimagable polymer, or photosensitive silicone dielectrics, such as SINR-3010 by Shin-Etsu Chemical Co., Ltd. Joint Stock Company Japan 6-1, Ohtemachi 2-Chome Chiyoda-Ku, Tokyo, Japan under the trademark ShinEtsu®.

Cavitation barrier layer 142, barrier layer 158, and nozzle plate 160 define a firing chamber 148 having nozzle 150 providing an opening thereto. Electrical contact 144 is upon cavitation barrier layer 142. The ink jet print head seen in FIG. 13 is in communication with a thermal ink jet printer 156 through a lead 154 to electrical contact 144. FIG. 13 can be compared to FIG. 6b in that gate electrodes 42 of FIG. 6b are electrically isolated one from another by deposited oxide layer 44 there between which also prevents current from flowing between active region 38 of the first FET and active region 37 of the second FET. Similarly, gate electrode 120 of FIG. 13 is electrically isolated from other gate electrodes by deposited oxide layers 118a, 118b on opposite sides of gate electrode 120. Such other gate electrodes having associated active regions can be situated upon semiconductor substrate 102 to the left and to the right of gate electrode 120 with respect to FIG. 13. As such, deposited oxide layers 118a, 118b prevent current from flowing between each of the primary and secondary active regions 108, 114 to any active region that is respectively adjacent thereto.

In operation of the embodiment seen in FIG. 13, the firing chamber 148 contains a fluid to be ejected out of opening 150. The fluid flows through a slot and into the firing chamber 148 via channels (not shown) terminating at firing chamber 148. Propagation of a current or a “fire signal” through the resistor layer 134 causes fluid in firing chamber 148 to be heated and expelled through opening 150.

FIG. 14 illustrates a print cartridge 10 of the present invention. A print head 16, such as that seen in FIG. 13, is a component of the print cartridge 10 on a surface thereof. A fluid reservoir 14, depicted in phantom within print cartridge 10 in FIG. 11, contains a fluid that is supplied to print head 16. A plurality of nozzles 150 on print head 16 are also seen in FIG. 12. In one embodiment, the nozzles 150 are in a nozzle plate 160.

Growing field oxide regions by thermal oxidation depletes dopants from the material being oxidized. This depletion lowers the threshold voltage of a parasitic transistor created by interconnect lines running over the field oxide regions, which in turn limits the maximum operating voltage that can be applied to a circuit without turning these parasitic devices on and causing excessive leakage. The method of the present invention proposes a deposition of an oxide, instead of a thermal growth of an oxide, so as to not deplete dopants from underlying materials. As such, a deposited oxide that is used to electrically isolate drive transistors from each other will not have the detrimental effect on the threshold voltage of parasitic devices. Thus, the maximum possible operating voltage that can be applied to a circuit will be increased in comparison to a conventional field oxide isolation process. The foregoing benefits also allow a simpler circuit design. Particularly, routing of interconnect metal and creation of parasitic leakage paths are less of a concern. Additionally, the drive transistor can operate at a higher operating voltage, if so desired.

The method of the present invention minimizes processing steps to fabricate an electrically isolated gate electrode. Various processes can be used for the method of the present invention of gate isolation. A pre-diffusion clean of a semiconductor substrate is followed by a deposition of silicon dioxide. An active area pattern of the silicon dioxide is performed, and then a isotropic buffered silicon dioxide etch of silicon dioxide can be performed to open the expose active areas. The pattern can then be stripped, a prediffusion clean is performed, and the gate oxide is grown.

Due to the costs of clean room fabrication of semiconductor devices, each step in a fabrication process is expensive in terms of time and materials. Moreover, each step introduces a potential for error in processing and handling, resulting in manufacturing defects. As such, it is advantageous to decrease the time that a wafer spends in a clean room as well as the number of steps performed upon a wafer undergoing fabrication. This advantage increases yield by a reduction in the number of fabrication steps to produce a device. The implementations disclosed herein for electrically isolating a gate electrode of a drive transistor by using a deposited oxide instead of a field oxide provide the desired result of reducing cost and increasing yield by having less processing. By way of example, the patterning and oxidizing for forming thermally grown field oxide are processing steps that can be avoided. The lower fabrication costs for ink jet print heads in turn lower the cost per printed page.

It should be recognized that, in addition to the thermal ink jet print head embodiments described above, this invention is also applicable to alternative digital printing and drop formation technologies including: medical devices, impact printing, mechanically actuated drop ejection, such as piezoelectric drop ejection, and flextensional drop ejection.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A semiconductor device comprising:
a semiconductor substrate having a first surface;
a pair of active areas formed in the first surface;
a deposited oxide layer proximate the active areas; and
a gate over the first surface between the pair of active areas.

2. The semiconductor device of claim 1, further comprising a thermal oxide layer disposed between the deposited oxide layer and the first surface of the semiconductor substrate.

3. The semiconductor device of claim 1, wherein the thickness of the deposited oxide layer varies across the active areas.

4. The semiconductor device of claim 1, wherein the active areas are n-doped regions.

5. The semiconductor device of claim 1, wherein the semiconductor substrate is P-type silicon.

6. The semiconductor device of claim 1, wherein the gate is comprised of a gate oxide layer and a poly silicon layer.

7. A method of making a semiconductor device comprising:
depositing a layer of oxide proximate a first surface of a semiconductor substrate;
forming a gate oxide layer on the first surface, adjacent to the deposited oxide layer;
forming a pair of active areas in the first surface, adjacent the deposited oxide layer and gate oxide layer;
forming a gate electrode by depositing a conductive layer over the gate oxide layer;
depositing a dielectric layer over the gate electrode, active areas, and deposited oxide layer; and
forming electrical contacts to the pair of active areas and the gate electrode.

8. The method of claim 7, further comprising thermally growing a thermal oxide layer before depositing the layer of oxide on the first surface of the semiconductor substrate.

9. The method of claim 7, wherein the semiconductor substrate is P type silicon.

10. The method of claim 7, wherein the active areas are formed by impurity implant and diffusion.

11. The method of claim 7, wherein the active areas are n-doped regions.

12. The method of claim 7, wherein the conductive layer over the gate oxide layer is polysilicon.

13. The method of claim 7, wherein the dielectric layer is silicon dioxide.

14. An print cartridge comprising:
a reservoir of fluid; and
a print head, said print head including:
a semiconductor substrate having a first surface;
a pair of active areas formed in the first surface;
a deposited oxide layer proximate the active areas; and
a gate electrode over the first surface between the pair of active areas.

15. The print cartridge of claim 14, further comprising a plurality of thin layers disposed over the first surface, the thin film layers including fluid ejection elements.

16. The print cartridge of claim 15, further comprising:
an orifice layer disposed over the thin film layers, the orifice layer defining a plurality of fluid ejection chambers.

17. The print cartridge of claim 15, wherein said fluid ejection elements are heater resistors.

18. The print cartridge of claim 16, wherein said fluid ejection elements are piezoelectric actuators.

19. A method of manufacturing a fluid ejection device, the method comprising:
forming first and second active areas in a first surface of a semiconductor substrate;
depositing a current prevention layer on the first surface in between the first and second active areas;
forming a gate oxide on the first surface adjacent to the second active area; and
forming a gate electrode for a drive transistor of the fluid ejection device on the gate oxide, wherein the current prevention layer minimizes current flow between the first and second active areas and the gate electrode.

20. The method of claim 19, wherein the current prevention layer is a dielectric.

21. The method of claim 19, wherein the current prevention layer is an oxide.
